(19) United States
(12) Patent Application Publication
(10) Pub. No.: US 2025/0273168 A1
(43) Pub. Date: Aug. 28, 2025

(54) GATE DRIVING CIRCUIT AND DISPLAY APPARATUS INCLUDING THE SAME

(71) Applicant: LG Display Co., Ltd., Seoul (KR)

(72) Inventors: Hyun Soo GONG, Paju-si (KR); Young Ho KIM, Paju-si (KR)

(73) Assignee: LG Display Co., Ltd., Seoul (KR)

(21) Appl. No.: 19/065,105

(22) Filed: Feb. 27, 2025

(30) Foreign Application Priority Data
Feb. 28, 2024 (KR) 10-2024-0028562

(51) Int. Cl. G09G 3/3266; G06F 3/044; G09G 3/00

(52) U.S. Cl. CPC G09G 3/3266; G06F 3/0443; G09G 3/035; G09G 2300/023; G09G 2310/021; G09G 2310/0213; G09G 2310/0286; G09G 2320/0204; G09G 2330/023; G09G 2330/04; G09G 2340/0435; G09G 2354/00; G09G 2360/14

(57) ABSTRACT

In one or more examples, a display apparatus includes a display panel configured to display an image and a gate driver connected to gate lines of the display panel and configured to output a scan signal which is to be applied to the gate lines, based on a clock signal. The clock signal includes a toggling omission time. A gate driving circuit is also disclosed.

### CROSS-REFERENCE TO RELATED APPLICATIONS

This application claims the benefit of and priority to Korean Patent Application No. 10-2024-0028562 filed on Feb. 28, 2024, the entire contents of which are incorporated herein by reference for all purposes as if fully set forth herein.

### BACKGROUND

### 1. Technical Field

The present disclosure relates to a gate driving circuit and a display apparatus including the same.

### 2. Description of the Related Art

As information technology advances, the market for display apparatuses which are connection mediums connecting a user to information is growing. Therefore, the use of display apparatuses such as light emitting display apparatuses, quantum dot display (QDD) apparatuses, and liquid crystal display (LCD) apparatuses is increasing.

The display apparatuses described above include a display panel which includes a plurality of subpixels, a driver which outputs a driving signal for driving the display panel, and a power supply which generates power which is to be supplied to the display panel or the driver.

In such display apparatuses, when the driving signal (for example, a scan signal and a data signal) is supplied to each of the subpixels provided in the display panel, a selected subpixel may transmit light or may self-emit light, and thus, an image may be displayed.

The description of the related art should not be assumed to be prior art merely because it is mentioned in or associated with this section. The description of the related art includes information that describes one or more aspects of the subject technology, and the description in this section does not limit the invention.

### SUMMARY

In one or more aspects, the present disclosure may integrate some of signals, which are for driving of a display panel, into one signal (for example, a clock signal capable of integration) and may minimize a load value (a line load or a driving load) which is an undesired burden on each signal, thereby decreasing the power consumption of a display apparatus.

To overcome the aforementioned problem of the related art, the present disclosure may provide a gate driving circuit and a display apparatus including the same.

To achieve these objects and other advantages and in accordance with the purpose of the disclosure, as embodied and broadly described herein, in one or more aspects, a display apparatus includes: a display panel configured to display an image; and a gate driver connected to gate lines of the display panel and configured to output a scan signal which is to be applied to the gate lines, based on a clock signal, wherein the clock signal includes a toggling omission time.

Toggling of the clock signal may be omitted for a time at which an output of a scan signal of an on voltage is completed.

The clock signal may be maintained in a direct current (DC) state for the time at which the output of the scan signal of the on voltage is completed.

The gate driver may include a plurality of stages, the plurality of stages are divided into a first group of stages and a second group of stages, the first group of stages are configured to apply the scan signal to gate lines of a first display area of the display panel, the second group of stages are configured to apply the scan signal to gate lines of a second display area of the display panel, the first group of stages may be connected to first group clock signal lines, the second group of stages may be connected to second group clock signal lines, and the first display area is different from the second display area.

The first group clock signal lines may include a first group odd clock signal line connected to a scan signal generator of an odd stage of the first group of stages and a first group even clock signal line connected to a scan signal generator of an even stage of the first group of stages, and the second group clock signal lines may include a second group odd clock signal line connected to a scan signal generator of an odd stage of the second group of stages and a second group even clock signal line connected to a scan signal generator of an even stage of the second group of stages.

A clock signal applied to the first group clock signal lines may be toggled for a first time of a vertical synchronization signal, and then, is put in a DC state for a second time, and a clock signal applied to the second group clock signal lines may be put in a DC state for the first time of the vertical synchronization signal, and then, is toggled for the second time.

The first group of stages may sequentially apply a scan signal of an on voltage to the gate lines of the first display area for the first time of the vertical synchronization signal, and the second group of stages may sequentially apply the scan signal of the on voltage to the gate lines of the second display area for the second time of the vertical synchronization signal.

The first group clock signal lines and the second group clock signal lines may be combined into one clock signal line.

In another aspect of the present disclosure, a display apparatus may include: a display panel configured to display an image; and a gate driver connected to gate lines of the display panel and configured to output a scan signal which is to be applied to the gate lines, based on a clock signal, wherein the clock signal includes a toggling time and a toggling omission time.

The toggling omission time may correspond to a time at which an output of a scan signal of an on voltage is completed.

The clock signal may be maintained in a DC state for the toggling omission time.

The display panel may comprise a first display area and a second display area different from the first display area, first group clock signals for driving the first display area are toggled for the toggling time corresponding to a first time of a vertical synchronization signal, and are omitted for the toggling omission time corresponding to a second time of the vertical synchronization signal, and second group clock signals for driving the second display area are toggled for the toggling time corresponding to the second time of the vertical synchronization signal, and are omitted for the toggling omission time corresponding to the first time of the vertical synchronization signal.

In another aspect of the present disclosure, a gate driving circuit includes: a plurality of clock signal lines; and a plurality of stages configured to output a scan signal, based on a clock signal transferred through the plurality of clock signal lines, wherein the clock signal includes a toggling omission time.

Toggling of the clock signal may be omitted for a time at which an output of a scan signal of an on voltage is completed.

The clock signal may be maintained in a DC state for the toggling omission time.

The plurality of stages may be divided into a first group of stages and a second group of stages, the plurality of clock signal lines are divided into first group clock signal lines transmitting first group clock signals and second group clock signal lines transmitting second group clock signals, wherein the first group of stages are connected to the first group clock signal lines, wherein the second group of stages are connected to the second group clock signal lines, wherein the first group clock signals are toggled for a first time of a vertical synchronization signal, and then, are put in a direct current state for a second time, and wherein the second group clock signals are put in a DC state for the first time of the vertical synchronization signal, and then, are toggled for the second time.

In one or more aspects, the present disclosure may integrate some of signals, which are for driving of a display panel, into one signal (for example, a clock signal capable of integration) and may divide a region of the display panel driven by each signal, and thus, may minimize a load value (a line load or a driving load) which is an undesired burden on each signal. In addition, in one or more aspects, the present disclosure may minimize a load value (a line load or a driving load) which is an undesired burden on each signal, thereby decreasing the power consumption of a display apparatus.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is a block diagram schematically illustrating a display apparatus, and

FIG. 2 is a block diagram illustrating a configuration of a gate driver in a display apparatus;

FIG. 3 is a cross-sectional view illustrating a stack structure of a display panel;

FIG. 4 is an example diagram illustrating some of elements included in a subpixel according to a first embodiment,

FIG. 5 is an example diagram illustrating a shift register included in a gate driver according to a first embodiment,

FIG. 6 is a waveform diagram illustrating clock signals applied to clock signal lines of FIG. 5 according to a first embodiment, and

FIG. 7 is a waveform diagram for describing toggling of the clock signals applied to the clock signal lines of FIG. 5 according to a first embodiment;

FIG. 8 is a diagram illustrating a circuit configuration of a subpixel according to a second embodiment, and

FIG. 9 is a diagram for describing a driving characteristic of a display panel provided based on a subpixel according to a second embodiment; and

FIG. 10 is an example diagram illustrating a shift register included in a gate driver according to a second embodiment,

FIG. 11 is a circuit configuration diagram illustrating an arbitrary stage in FIG. 10 according to a second embodiment,

FIG. 12 is a diagram for describing toggling of clock signals applied to clock signal lines of FIG. 10 according to a second embodiment, and

FIG. 13 is a diagram for describing an advantage based on toggling of clock signals according to a second embodiment.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Hereinafter, the present disclosure will be described more fully with reference to the accompanying drawings, in which example embodiments of the disclosure are shown. The disclosure may, however, be embodied in many different forms and should not be construed as being limited to the embodiments set forth herein; rather, these embodiments are provided so that this disclosure will be thorough and complete, and will fully convey the concept of the disclosure to those skilled in the art.

In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, components, electrodes, structures, transistors, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise. For example, an element may be one or more elements. An element may include a plurality of elements. The word “exemplary” is used to mean serving as an example or illustration. Embodiments are example embodiments. An embodiment is an example embodiment. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, components, electrodes, structures, transistors, regions, areas, portions, and/or the like) are described using any of the terms such as “on,” “over,” “under,” “above,” “upper,” “below,” “lower,” “beneath,” “near,” “close to,” “adjacent to,” “beside,” “next to,” “at or on a side of,” and/or the like indicating a position or location, one or more other elements may be located between the two elements unless a more limiting term, such as “immediate (ly),” “direct (ly),” or “close (ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “left,” “right,” “upper,” “lower,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “following,” “subsequent,” “next,” “before,” “prior to,” or the like, a case that is not consecutive or not sequential may be included and thus one or more other events may occur therebetween, unless a more limiting term, such as “just,” “immediate (ly),” or “direct (ly),” is used.

It is understood that, although the terms “first,” “second,” and the like may be used herein to describe various elements (e.g., layers, films, components, electrodes, structures, transistors, regions, areas, portions, steps, operations, and/or the like), these elements should not be limited by these terms, for example, to any particular order, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

The expression that an element (e.g., layer, film, component, electrode, structure, transistor, section, member, part, region, area, portion, or the like) “is engaged” with another element may be understood, for example, as that the element may be either directly or indirectly engaged with the another element. The term “is engaged” or similar expressions may refer to a term such as “is in contact,” “overlaps,” “intersects,” “is connected,” “is coupled,” “is combined,” “is linked,” “is provided,” “is disposed,” “interacts,” or the like. The engagement may involve one or more intervening elements disposed or interposed between the element and the another element, unless otherwise specified. Further, the element may be engaged at least partially or entirely (or completely) with the another element, unless otherwise specified. Further, the element may be included in at least one of two or more elements that are engaged with each other. Similarly, the another element may be included in at least one of two or more elements that are engaged with each other. When the element is engaged with the another element, at least a portion of the element may be engaged with at least a portion of the another element. The term “with another element” or similar expressions may be understood as “another element,” or “with, to, in, or on another element,” as appropriate by the context. Similarly, the term “with each other” may be understood as “each other,” or “with, to, or on each other,” as appropriate by the context.

The phrase “through” may be understood, for example, to be at least partially through or entirely through.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, at least one of a plurality of elements can represent (i) one element of the plurality of elements, (ii) some elements of the plurality of elements, or (iii) all elements of the plurality of elements. Further, “at least some,” “at least some portions,” “at least some parts,” “at least a portion,” “at least one or more portions,” “at least a part,” “at least one or more parts,” “at least some elements,” “one or more,” or the like of a plurality of elements can represent (i) one element of the plurality of elements, (ii) a portion (or a part) of the plurality of elements, (iii) one or more portions (or parts) of the plurality of elements, (iv) multiple elements of the plurality of elements, or (v) all of the plurality of elements. Moreover, “at least some,” “at least some portions,” “at least some parts,” “at least a portion,” “at least one or more portions,” “at least a part,” “at least one or more parts,” or the like of an element can represent (i) a portion (or a part) of the element, (ii) one or more portions (or parts) of the element, or (iii) the element, or all portions of the element.

The expression of a first element, a second elements “and/or” a third element should be understood as one of the first, second and third elements or as any or all combinations of the first, second and third elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element is referred to as being “between” at least two elements, the element may be the only element between the at least two elements, or one or more intervening elements may also be present.

In one or more aspects, the phrases “each other” and “one another” may be used interchangeably simply for convenience unless stated otherwise.

In one or more aspects, the phrases “one or more among” and “one or more of” may be used interchangeably simply for convenience unless stated otherwise. In one or more aspects, unless stated otherwise, the term “mth” may refer to “mnd” (e.g., 2nd where m is 2), or “mrd” (e.g., 3rd where m is 3), and m may be a natural number or a whole number.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in more detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for the convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

A display apparatus according to one or more aspects of the present disclosure may be implemented as a light emitting display apparatus or a quantum dot display (QDD) apparatus. Hereinafter, for convenience of description, a light emitting display apparatus self-emitting light based on an inorganic light emitting diode or an organic light emitting diode will be described for example.

Moreover, a thin film transistor (TFT) described below may be implemented with an n-type TFT, a p-type TFT, or a combination of an n-type TFT and a p-type TFT. A TFT may be a three-electrode element including a gate, a source, and a drain. The source may be an electrode which provides a carrier to a transistor. In the TFT, a carrier may start to flow from the source. The drain may be an electrode where the carrier flows from the TFT to the outside. That is, in the TFT, the carrier flows from the source to the drain.

In the p-type TFT, because a carrier is a hole, a source voltage may be higher than a drain voltage so that the hole flows from the source to the drain. In the p-type TFT, because the hole flows from the source to the drain, a current may flow from the source to the drain. On the other hand, in the n-type TFT, because a carrier is an electron, a source voltage may be lower than a drain voltage so that the electron flows from the source to the drain. In the n-type TFT, because the electron flows from the source to the drain, a current may flow from the drain to the source. However, a source and a drain of a TFT may switch therebetween based on a voltage applied thereto. Based thereon, in the following description, one of a source and a drain will be described as a first electrode, and the other of the source and the drain will be described as a second electrode.

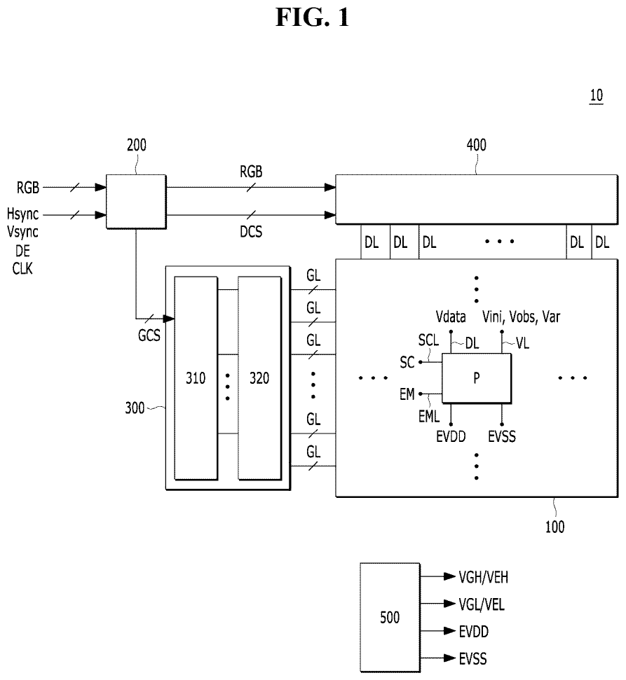

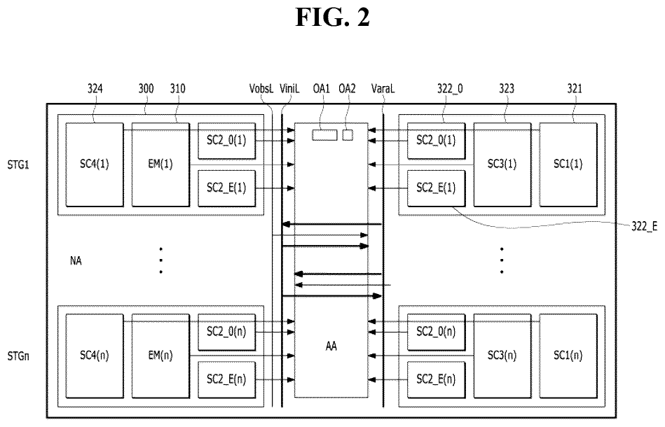

FIG. 1 is a block diagram schematically illustrating a display apparatus 10, and FIG. 2 is a block diagram illustrating a configuration of a gate driver in the display apparatus 10.

As illustrated in FIG. 1, the display apparatus 10 may include a display panel 100 which includes a plurality of subpixels SP, a controller 200, a gate driver (or a gate driving circuit) 300 which supplies a gate signal to the plurality of subpixels SP, a data driver 400 which supplies a data signal (or a data voltage) to the plurality of subpixels SP, and a power supply 500 which supplies power to the plurality of subpixels SP.

The display panel 100 may include a display area (see AA of FIG. 2) where the plurality of subpixels SP are provided and a non-display area (see NA of FIG. 2) which is disposed to surround the display area AA and where the gate driver 300 and the data driver 400 are disposed.

In the display panel 100, a plurality of gate lines GL and a plurality of data lines DL may intersect with one another, and each of the plurality of subpixels SP may be connected to a gate line GL and a data line DL. In detail, one subpixel SP may be supplied with a gate signal from the gate driver 300 through the gate line GL, may be supplied with a data signal from the data driver 400 through the data line DL, and may be supplied with a high-level voltage EVDD and a low-level voltage EVSS from the power supply 500.

The gate line GL may transfer a scan signal SC and an emission control signal EM to the plurality of subpixels SP, and the data line DL may transfer a data voltage Vdata to the plurality of subpixels SP. According to various embodiments, the gate line GL may include a plurality of scan lines SCL for supplying the scan signal SC and a plurality of emission control lines EML for supplying the emission control signal EM. The plurality of subpixels SP may be supplied with voltages Vini, Var, and Vobs through a plurality of voltage lines VL. The voltages Vini, Var, and Vobs applied through the plurality of voltage lines VL will be described below.

Each of the plurality of subpixels SP may include a subpixel driving circuit. The subpixel driving circuit may include a plurality of switching elements, a driving element, and a capacitor. The switching element and the driving element may each be configured as a TFT. A switching transistor may be turned on based on the scan signal SC supplied through the scan line SCL and the emission control signal EM supplied through the emission control line EML. A driving transistor may control the amount of current (control the amount of emitted light) supplied to a light emitting device OLED, based on the data voltage Vdata.

The display panel 100 may be implemented as a non-transmissive display panel or a transmissive display panel. The transmissive display panel may be applied to a transparent display apparatus which displays an image on a screen thereof and enables a real thing of a background to be seen. The display panel 100 may be implemented as a flexible display panel. The flexible display panel may use a plastic substrate. Each of the plurality of subpixels SP may be divided into a red subpixel, a green subpixel, and a blue subpixel for color implementation. Each of the plurality of subpixels SP may further include a white subpixel.

Touch sensors may be disposed in the display panel 100. A touch input may be sensed by using separate touch sensors, or may be sensed through the plurality of subpixels SP. The touch sensors may be arranged as an on-cell type or an add-on type in a screen of the display panel 100, or may be implemented as in-cell type touch sensors embedded in the display panel 100.

The controller 200 may process image data RGB input from the outside to supply to the data driver 400, based on a size and a resolution of the display panel 100. The controller 200 may generate a gate control signal GCS and a data control signal DCS by using synchronization signals (for example, a dot clock signal CLK, a data enable signal DE, a horizontal synchronization signal Hsync, and a vertical synchronization signal Vsync) input from the outside. The controller 200 may supply the gate control signal GCS to the gate driver 300 to control an operation timing of the gate driver 300. The controller 200 may supply the data control signal DCS to the data driver 400 to control an operation timing of the data driver 400. The controller 200 may synchronize the operation timing of the gate driver 300 with the operation timing of the data driver 400 by using the gate control signal GCS and the data control signal DCS.

The controller 200 may be configured to be coupled to various processors (for example, a microprocessor, a mobile processor, and an application processor), based on a device mounted thereon. A host system disposed a previous end with respect to the controller 200 may be one of a television (TV) system, a set-top box, a navigation system, a personal computer (PC), a home theater system, a mobile device, a wearable device, and an automotive system.

The controller 200 may multiply an input frame frequency by i (where i may be a positive integer of more than 0) times to control an operation timing of the display panel driver, based on a frame frequency of an input frame frequency X i Hz. The input frame frequency may be about 60 Hz in national television standards committee (NTSC) scheme and may be about 50 Hz in phase-alternating line (PAL) scheme.

The controller 200 may drive the display panel 100 at various refresh rates. The controller 200 may drive the display panel 100 as a switchable type in a variable refresh rate (VRR) mode, namely, between a first refresh rate and a second refresh rate. For example, the controller 200 may simply change a speed of a clock signal, or may generate a synchronization signal so that a horizontal blank or a vertical blank occurs, or may drive the gate driver 300 in a mask mode, thereby driving the display panel 100 at various refresh rates.

A voltage level of the gate control signal GCS output from the controller 200 may be shifted to a gate on voltage VGL (VEL) and a gate off voltage VGH (VEH) by a level shifter (not shown) and may be supplied to the gate driver 300. The level shifter may shift a low level voltage of the gate control signal GCS to a gate low voltage VGL and may shift a high level voltage of the gate control signal GCS to a gate high voltage VGH. The gate control signal GCS may include a start signal and a clock signal.

The gate driver 300 may supply the gate signal to the gate line GL, based on the gate control signal GCS supplied from the controller 200. The gate driver 300 may be disposed at one side or both sides of the display panel 100 in a gate in panel (GIP) type.

The gate driver 300 may sequentially output the gate signal to the plurality of gate lines GL, based on control by the controller 200. The gate driver 300 may shift the gate signal by using a shift register, and thus, may sequentially supply the signals to the gate lines GL.

In an organic light emitting display apparatus, the gate signal may include the scan signal SC and the emission control signal EM. The scan signal SC may include a scan pulse which swings between a gate on voltage VGL and a gate off voltage VGH. The emission control signal EM may include an emission control signal pulse which swings between a gate on voltage VEL and a gate off voltage VEH. The scan pulse may select subpixels SP of a line in which a data voltage Vdata is to be written. The emission control signal EM may define an emission time of each of the subpixels SP.

The gate driver 300 may include an emission control signal driver 310 and one or more scan drivers 320. The emission control signal driver 310 may output the emission control signal pulse in response to a start signal and a clock signal from the controller 200 and may sequentially shift the emission control signal pulse according to the clock signal. The one or more scan drivers 320 may output the scan pulse in response to the start signal (or a start pulse) and the clock signal (or a shift clock) from the controller 200 and may shift the scan pulse, based on a clock signal timing.

The data driver 400 may convert the image data RGB into a data voltage Vdata, based on the data control signal DCS supplied from the controller 200, and may output the data voltage Vdata through the data line DL.

In FIG. 1, it is illustrated that the data driver 400 is disposed as one type at one side of the display panel 100, but the number and arrangement positions of data drivers 400 are not limited thereto. That is, the data driver 400 may be configured with a plurality of integrated circuits (ICs) and may be provided in plurality, and the plurality of data drivers 400 may be divided and arranged at one side of the display panel 100.

The power supply 500 may generate a direct current (DC) power needed for driving of the display panel driver and a subpixel array of the display panel 100 by using a DC-DC converter. The DC-DC converter may include a charge pump, a regulator, a buck converter, and a boost converter. The power supply 500 may receive a DC input voltage applied from the host system (not shown) to generate the gate on voltage VGL (VEL). The power supply 500 may generate DC voltages such as the gate off voltage VGH (VEH), the high-level voltage EVDD, and the low-level voltage EVSS. The gate on voltage VGL (VEL) and the gate off voltage VGH (VEH) may be supplied to the level shifter (not shown) and the gate driver 300. The high-level voltage EVDD and the low-level voltage EVSS may be supplied to the plurality of subpixels SP in common.

As illustrated in FIGS. 1 and 2, the gate driver 300 may include the emission control signal driver 310 and the scan driver 320. The scan driver 320 may include first to fourth scan drivers 321 to 324. Also, the second scan driver 322 may include odd-numbered second scan drivers 322_O and even-numbered second scan drivers 322_E.

Shift registers configuring the gate driver 300 may be configured to be symmetric at both sides of the display area AA. The shift register of one side of the display area AA may include second scan drivers 322_O and 322_E, the fourth scan driver 324, and the emission control signal driver 310, and the shift register of the other side of the display area AA may include the first scan driver 321, second scan drivers 322_O and 322_E, and the third scan driver 323. In FIG. 2, an example is illustrated where the odd-numbered second scan driver 322_O and the even-numbered second scan driver 322_E have a structure where an odd-numbered subpixel and an even-numbered subpixel share the second scan driver 322. Accordingly, the emission control signal driver 310 and the first to fourth scan drivers 321 to 324 may be differently arranged, but are not limited thereto.

Stages STG1 to STGn of the shift register may respectively include first scan signal generators SC1(1) to SC1(n), second scan signal generators SC2_O(1) to SC2_O(n) and SC2_E(1) to SC2_E(n), third scan signal generators SC3(1) to SC3(n), fourth scan signal generators SC4(1) to SC4(n), and emission control signal generators EM(1) to EM(n). In FIG. 2, an N^{th} stage STGn of the shift register is illustrated as a last stage. However, at least one dummy stage may also be disposed at a previous stage with respect to the first stage STG1 of the shift register and a next stage with respect to the N^{th} stage STGn of the shift register.

The first scan signal generators SC1(1) to SC1(n) may respectively output first scan signals SC1(1) to SC1(n) through first scan lines SCL1 of the display panel 100. The second scan signal generators SC2(1) to SC2(n) may respectively output second scan signals SC2(1) to SC2(n) through second scan lines SCL2 of the display panel 100. The third scan signal generators SC3(1) to SC3(n) may respectively output third scan signals SC3(1) to SC3(n) through third scan lines SCL3 of the display panel 100. The fourth scan signal generators SC4(1) to SC4(n) may respectively output fourth scan signals SC4(1) to SC4(n) through fourth scan lines SCL4 of the display panel 100. The emission control signal generators EM(1) to EM(n) may respectively output emission control signals EM(1) to EM(n) through emission control lines EML of the display panel 100.

The first scan signals SC1(1) to SC1(n) may be used as a signal for driving an A^{th} transistor (for example, a compensation transistor) included in the subpixel driving circuit. The second scan signals SC2(1) to SC2(n) may be used as a signal for driving a B^{th} transistor (for example, a data supply transistor) included in the subpixel driving circuit. The third scan signals SC3(1) to SC3(n) may be used as a signal for driving a C^{th} transistor (for example, a bias transistor) included in the subpixel driving circuit. The fourth scan signals SC4(1) to SC4(n) may be used as a signal for driving a D^{th} transistor (for example, an initialization transistor) included in the subpixel driving circuit. The emission control signals EM(1) to EM(n) may be used as a signal for driving an E^{th} transistor (for example, an emission control transistor) included in the subpixel driving circuit. For example, when the emission control transistor is controlled by using the emission control signals EM(1) to EM(n), an emission time of a light emitting device may vary.

A bias voltage line VobsL transferring a bias voltage, a first initialization voltage line VaraL transferring a first initialization voltage, and a second initialization voltage line ViniL transferring a second initialization voltage may be disposed between the gate driver 300 and the display area AA.

In the drawing, each of the bias voltage line VobsL, the first initialization voltage line VaraL, and the second initialization voltage line ViniL is illustrated as being disposed at one side of a left side or a right side of the display area AA, but is not limited thereto and may be disposed at both sides, or even when being disposed at one side, a position is not limited to the left side or the right side.

Furthermore, one or more optical regions OA1 and OA2 may be disposed in the display area AA. The optical regions OA1 and OA2 may be disposed to overlap one or more optical electronic devices such as an imaging device such as a camera (an image sensor) and a sensing sensor such as a proximity sensor and an illumination sensor.

The optical regions OA1 and OA2 may have a light transmissive structure, for an operation of an optical electronic device, and thus, may have a transmittance of a certain level or more. In other words, the number of pixels P per unit area in the optical regions OA1 and OA2 may be less than the number of pixels per unit area in a normal region, except the optical regions OA1 and OA2, of the display area AA. That is, a resolution of each of the optical regions OA1 and OA2 may be lower than that of the normal region of the display area AA.

In the optical regions OA1 and OA2, the light transmissive structure may be configured by patterning a cathode electrode in a portion where a subpixel is not disposed. In this case, the patterned cathode electrode may be removed by using a laser, or by using a material such as a cathode deposition prevention layer, the cathode electrode may be selectively patterned.

Moreover, in the optical regions OA1 and OA2, the light transmissive structure may be configured by separately forming a light emitting device and a subpixel driving circuit included in a subpixel. In other words, the light emitting device of the subpixel may be disposed in the optical regions OA1 and OA2, and a plurality of transistors configuring the subpixel driving circuit may be disposed near the optical regions OA1 and OA2, and thus, the light emitting device may be electrically connected to the subpixel driving circuit through a transparent metal layer.

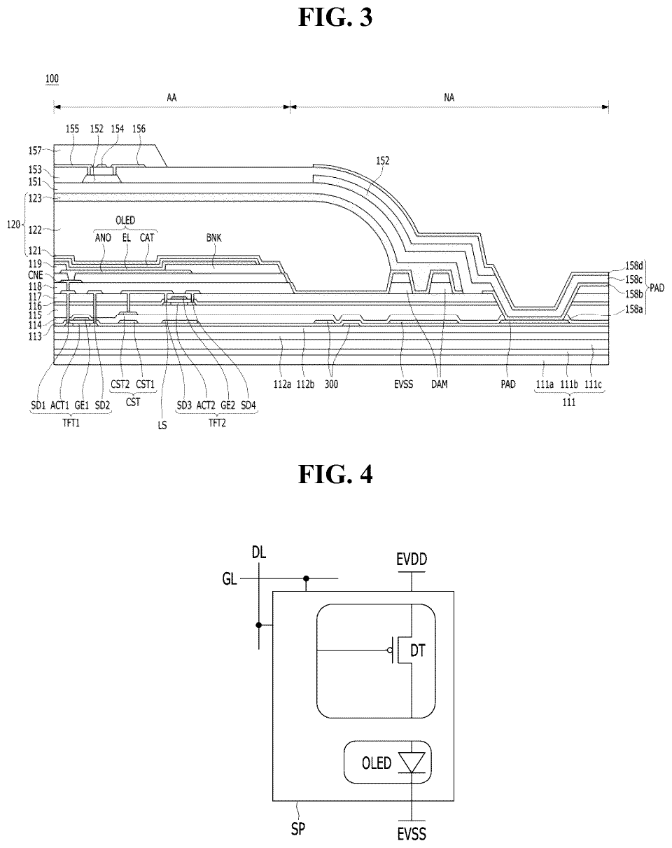

FIG. 3 is a cross-sectional view illustrating a stack structure of a display panel 100.

As illustrated in FIG. 3, transistors TFT1 and TFT2 and a capacitor CST for driving a light emitting device OLED disposed in a display area AA may be disposed on a substrate 111 of the display panel 100. The transistors TFT1 and TFT2 may include one thin film transistor of a switching thin film transistor and a driving transistor including a polycrystalline semiconductor material and an oxide thin film transistor including an oxide semiconductor material. In this case, a thin film transistor including a polycrystalline semiconductor material may be referred to as a polycrystalline thin film transistor TFT1, and a thin film transistor including an oxide semiconductor material may be referred to as an oxide thin film transistor TFT2. For example, the polycrystalline thin film transistor TFT1 may be a transistor connected to the light emitting device OLED, and the oxide thin film transistor TFT2 may be a transistor connected to the capacitor CST.

The substrate 111 may be implemented as a multi-layer 111a˜111c where an organic layers 111a and 111c and an inorganic layer 111b are alternately stacked. For example, in the substrate 111, an organic layers 111a and 111c such as polyimide and an inorganic layer 111b such as oxide silicon (SiO₂) may be alternately stacked.

A lower buffer layer 112a may be formed on the substrate 111. The lower buffer layer 112a may be for preventing the penetration of water from the outside and may use an SiO₂ layer which is stacked as a multilayer. An auxiliary buffer layer 112b may be further disposed on the lower buffer layer 112a, so as to protect elements from the penetration of water.

The polycrystalline thin film transistor TFT1 may be formed on the substrate 111. The polycrystalline thin film transistor TFT1 may use a polycrystalline semiconductor material as an active layer. The polycrystalline thin film transistor TFT1 may include a first active layer ACT1 including a channel through which an electron or a hole moves, a first gate electrode GE1, a first source electrode SD1, and a first drain electrode SD2. A first gate insulation layer 113 may be disposed between the first gate electrode GE1 and the first active layer ACT1 and may use an inorganic layer such as nitride silicon (SiNx) or a SiO₂ layer, which is stacked as a single layer or a multiplayer.

The first active layer ACT1 may include a first channel region, a first source region disposed at one side with respect to the first channel region, and a first drain region disposed at the other side with respect to the first channel region. The first source region and the first drain region may each be a region which is conductive by doping a Group 5 or 3 impurity ion (for example, phosphorus (P) or boron (B)) on an intrinsic polycrystalline semiconductor material at a certain concentration. The first channel region may allow a polycrystalline semiconductor material to maintain an intrinsic state and may provide a path through which an electron or a hole moves.

According to an embodiment, the polycrystalline thin film transistor TFT1 may be implemented in a top gate structure where the first gate electrode GE1 is disposed on the first active layer ACT1. Accordingly, a first electrode CST1 included in the capacitor CST and a light blocking layer LS included in the oxide thin film transistor TFT2 may be formed of the same material as that of the first gate electrode GE1. The first gate electrode GE1, the first electrode CST1, and the light blocking layer LS may be formed through one mask process, thereby reducing a mask process.

The first gate electrode GE1 may include a metal material. For example, the first gate electrode GE1 may be a single layer or a multilayer including one of molybdenum (Mo), aluminum (Al), chrome (Cr), gold (Au), titanium (Ti), nickel (Ni), neodymium (Nd), and copper (Cu), or an alloy thereof, but is not limited thereto. A first interlayer insulation layer 114 may be disposed on the first gate electrode GE1. The first interlayer insulation layer 114 may be implemented with SiO₂ or SiNx.

The display panel 100 may further include an upper buffer layer 115, a second gate insulation layer 116, and a second interlayer insulation layer 117, which are sequentially disposed on the first interlayer insulation layer 114, and the polycrystalline thin film transistor TFT1 may include a first source electrode SD1 and a first drain electrode SD2, which are formed on the second interlayer insulation layer 117 and are respectively connected to the first source region and the first drain region.

The first source electrode SD1 and the first drain electrode SD2 may be a single layer or a multilayer including one of Mo, Al, Cr, Au, Ti, Ni, Nd, and Cu, or an alloy thereof, but are not limited thereto.

The upper buffer layer 115 may separate the second active layer ACT2 of the oxide thin film transistor TFT2, implemented with an oxide semiconductor material, from the first active layer ACT1 implemented with a polycrystalline semiconductor material and may provide a basis for forming the second active layer ACT2.

The second gate insulation layer 116 may cover the second active layer ACT2 of the oxide thin film transistor TFT2. The second gate insulation layer 116 may be formed on the second active layer ACT2 implemented with an oxide semiconductor material, and thus, may be implemented as an inorganic layer. For example, the second interlayer insulation layer 116 may be SiO₂ or SiNx.

The second gate electrode GE2 may be configured with a metal material. For example, the second gate electrode GE2 may be a single layer or a multilayer including one of Mo, Al, Cr, Au, Ti, Ni, Nd, and Cu, or an alloy thereof, but are not limited thereto.

The oxide thin film transistor TFT2 may be formed on the upper buffer layer 115. The oxide thin film transistor TFT2 may include a second active layer ACT2 implemented with an oxide semiconductor material, a second gate electrode GE2 disposed on the second gate insulation layer 116, and a second source electrode SD3 and a second drain electrode SD4 which are disposed on the second interlayer insulation layer 117. The second active layer ACT2 may be implemented with an oxide semiconductor material and may include an intrinsic second channel region which is not doped with impurities and a second source region and a second drain region which are conductive by doping impurities.

The oxide thin film transistor TFT2 may further include a light blocking layer LS which is disposed under the upper buffer layer 115 to overlap the second active layer ACT2. The light blocking layer LS may prevent light from being incident on the second active layer ACT2 and may thus secure the reliability of the oxide thin film transistor TFT2. The light blocking layer LS may be formed of the same material as that of the first gate electrode GE1 and may be disposed on an upper surface of the first gate insulation layer 113. The light blocking layer LS may be electrically connected to the second gate electrode GE2 to configure a dual gate.

The second source electrode SD3 and the second drain electrode SD4 may be simultaneously formed of the same material on the second interlayer insulation layer 117 along with the first source electrode SD1 and the first drain electrode SD2, and thus, may reduce the number of mask processes.

Furthermore, the second electrode CST2 may be disposed on the first interlayer insulation layer 114 to overlap the first electrode CST1 and may thus implement the capacitor CST. For example, the second electrode CST2 may be a single layer or a multilayer including one of Mo, Al, Cr, Au, Ti, Ni, Nd, and Cu, or an alloy thereof.

The capacitor CST may store a data voltage, applied through a data line DL, during a certain period. The capacitor CST may include two electrodes corresponding to each other and a dielectric disposed therebetween. The first interlayer insulation layer 114 may be disposed between the first electrode CST1 and the second electrode CST2.

The first electrode CST1 and the second electrode CST2 of the capacitor CST may be electrically connected to the second source electrode SD3 or the second drain electrode SD4 of the oxide thin film transistor TFT2. However, an embodiment is not limited thereto, and a connection relationship of the capacitor CST may be changed based on a subpixel driving circuit.

A first planarization layer 118 and a second planarization layer 119 for planarizing a surface may be sequentially disposed on the subpixel driving circuit. The first planarization layer 118 and the second planarization layer 119 may each be an organic layer such as polyimide or acrylic resin. The light emitting device OLED may be formed on the second planarization layer 119.

The light emitting device OLED may include an anode electrode ANO, a cathode electrode CAT, and an emission layer EL disposed between the anode electrode ANO and the cathode electrode CAT. In a case where the subpixel driving circuit using in common a low-level voltage connected to the cathode electrode CAT is implemented, the anode electrode ANO may be disposed as a separate electrode for each subpixel. On the other hand, in a case where the subpixel driving circuit using in common a high-level voltage is implemented, the cathode electrode CAT may be disposed as a separate electrode for each subpixel.

The light emitting device OLED may be electrically connected to a driving element through a center electrode CNE disposed on the first planarization layer 118. For example, the anode electrode ANO of the light emitting device OLED and the first source electrode SD1 of the polycrystalline thin film transistor TFT1 configuring the subpixel driving circuit may be connected to each other by the center electrode CNE.

The anode electrode ANO may be connected to the center electrode CNE exposed through a contact hole passing through the second planarization layer 119. The center electrode CNE may be connected to the first source electrode SD1 exposed through a contact hole passing through the first planarization layer 118.

The center electrode CNE may function a medium which connects the first source electrode SD1 to the anode electrode ANO. The center electrode CNE may include a conductive material such as Cu, Ag, Mo, or Ti.

The anode electrode ANO may be formed in a multi-layer structure including a transparent conductive layer and an opaque conductive layer which is high in reflection efficiency. The transparent conductive layer may include a material, which is relatively large in work function value, such as indium tin oxide (ITO) or indium zinc oxide (IZO), and the opaque conductive layer may be formed in a single-layer or multi-layer structure which includes Al, Ag, Cu, lead (Pb), Mo, or Ti, or an alloy thereof. For example, the anode electrode ANO may be formed in a structure where a transparent conductive layer, an opaque conductive layer, and a transparent conductive layer are sequentially stacked, or may be formed in a structure where a transparent conductive layer and an opaque conductive layer are sequentially stacked. The emission layer EL may be formed by stacking a hole-related layer, an organic emission layer, and an electron-related layer on the anode electrode ANO in order or reverse order.

A bank layer BNK may be a subpixel definition layer which exposes the anode electrode ANO of each subpixel. The bank layer BNK may be formed of an opaque material (for example, black) so as to prevent light interference between adjacent subpixels. In this case, the bank layer BNK may include a light blocking material including at least one of a color pigment, organic black, and carbon.

The cathode electrode CAT may be formed on an upper surface and a lateral surface of the emission layer EL so as to be opposite to the anode electrode ANO with the emission layer EL therebetween. The cathode electrode CAT may be formed as one body to cover all of the display area AA. In a case where the cathode electrode CAT is applied to an organic light emitting display apparatus of a top emission type, the cathode electrode CAT may include a transparent conductive layer such as ITO or IZO.

An encapsulation layer 120 for preventing the penetration of water may be further disposed on the cathode electrode CAT. The encapsulation layer 120 may prevent the penetration of external water or oxygen into the emission layer EL vulnerable to external water or oxygen. To this end, the encapsulation layer 120 may include an at least one-layer inorganic encapsulation layer and an at least one-layer organic encapsulation layer, but is not limited thereto. The encapsulation layer 120 may include a first encapsulation layer 121, a second encapsulation layer 122, and a third encapsulation layer 123, which are sequentially stacked.

The first encapsulation layer 121 and the third encapsulation layer 123 may include an inorganic insulating material, which is capable of low temperature deposition, such as SiNx, SiOx, oxynitride silicon (SiON), or oxide aluminum (Al₂O₃). The first encapsulation layer 121 and the third encapsulation layer 123 may be deposited in a low temperature atmosphere, and thus, may prevent the damage of the emission layer EL vulnerable to a high temperature atmosphere when performing a deposition process of the first encapsulation layer 121 and the third encapsulation layer 123.

The second encapsulation layer 122 may perform a buffer function of decreasing a stress between layers caused by the bending of the display apparatus 10 and may planarize a step height between layers. The second encapsulation layer 122 may be formed on the substrate 111 where the first encapsulation layer 121 is formed and may include acryl resin, epoxy resin, phenolic resin, polyamide resin, polyimide resin, and polyethylene, or a non-photosensitive organic insulating material such as silicon oxycarbon (SiOC), or a photosensitive organic insulating material such as photo acryl, but an embodiment is not limited thereto.

In a case where the second encapsulation layer 122 is formed through an inkjet process, a dam DAM may be disposed to prevent the second encapsulation layer 122 from being diffused to an edge of the substrate 111. The dam DAM may be disposed closer to the edge of the substrate 111 than the second encapsulation layer 122. The dam DAM may prevent the second encapsulation layer 122 from being diffused to a pad region where a conductive pad disposed at an outermost portion of the substrate 111 is provided.

The dam DAM may be designed to prevent the diffusion of the second encapsulation layer 122, but in a case where the second encapsulation layer 122 is formed to flow over a height of the dam DAM when performing a process, the second encapsulation layer 122 which is an organic layer may be exposed at the outside, and due to this, water may penetrate into the light emitting device OLED. Accordingly, in order to solve such a problem, the dam DAM may be provided as ten or more to overlap each other.

The dam DAM may be disposed on the second interlayer insulation layer 117 of a non-display area NA. Also, the dam DAM may be formed simultaneously with the first planarization layer 118 and the second planarization layer 119. A lower layer of the dam DAM may be formed together when forming the first planarization layer 118, and an upper layer of the dam DAM may be formed together when forming the second planarization layer 119, and thus, the dam DAM may be stacked and formed in a double structure. Accordingly, the dam DAM may include the same insulating material as that of the first planarization layer 118 and the second planarization layer 119, but an embodiment is not limited thereto.

The dam DAM may be formed to overlap a low-level voltage line EVSS. For example, the low-level voltage line EVSS may be disposed in a lower layer of a region, where the dam DAM is disposed, of the non-display area NA. The low-level voltage line EVSS may be disposed more outward than the gate driver 300 and may surround the display area AA. For example, the low-level voltage line EVSS may include the same material as that of the first gate electrode GE1, but is not limited thereto and may include the same material as that of the second electrode CST2 or the first source electrode SD1 and the first drain electrode SD2. The low-level voltage line EVSS may be electrically connected to the cathode electrode CAT so as to apply the low-level voltage EVSS to a plurality of subpixels included in the display area AA.

A touch layer may be disposed on the encapsulation layer 120. In the touch layer, a touch buffer layer 151 may be disposed between the cathode electrode CAT of the light emitting device OLED and a touch sensor metal layer including touch electrodes 155 and 156 and touch electrode connection lines 152 and 154.

The touch buffer layer 151 may prevent external water or a chemical solution (for example, a developer or an etchant), which is used in a manufacturing process of the touch sensor metal layer disposed on the touch buffer layer 151, from penetrating into the emission layer EL including an organic material. Accordingly, the touch buffer layer 151 may prevent the damage of the emission layer EL vulnerable to the chemical solution or water.

The touch buffer layer 151 may include an organic insulating material which has a low dielectric constant of 1 to 3 and is capable of being formed at a low temperature of a certain temperature (for example, 100° C.) or less, so as to prevent the damage of the emission layer EL including an organic material vulnerable to a high temperature. For example, the touch buffer layer 151 may include an acrylic material, an epoxy-based material, or a siloxane-based material. The touch buffer layer 151 which includes an organic insulating material and has planarization performance may prevent the damage of the encapsulation layer 120 caused by the bending of an apparatus and the breakage of the touch sensor metal layer formed on the touch buffer layer 151.

According to a touch sensor structure based on a mutual capacitance, the touch electrodes 155 and 156 may be disposed on the touch buffer layer 151, and the touch electrodes 155 and 156 may be disposed to intersect with each other. The touch electrode connection lines 152 and 154 may electrically connect the touch electrodes 155 and 156 with each other. The touch electrode connection lines 152 and 154 and the touch electrodes 155 and 156 may be disposed in different layers with the touch insulation layer 153 therebetween. The touch electrode connection lines 152 and 154 may be disposed to overlap the bank layer BNK and may prevent a reduction in aperture ratio.

In the touch electrodes 155 and 156, a portion of the touch electrode connection line 152 may pass through an upper portion and a lateral surface of the encapsulation layer 120 and an upper portion and a lateral surface of the dam DAM and may be electrically connected to a touch driving circuit (not shown) through a touch pad PAD. A portion of the touch electrode connection line 152 may be supplied with a touch driving signal from a touch driving circuit and may transfer the touch driving signal to the touch electrodes 155 and 156, or may transfer touch sensing signals of the touch electrodes 155 and 156 to the touch driving circuit.

The touch pad PAD may include a first pad layer 158a including the same layer and material as those of the first gate electrode GE1, a second pad layer 158b including the same layer and material as those of the first source electrode SE1 and the first drain electrode DE1, a third pad layer 158c including the same layer and material as those of the touch electrode connection line 152, and a fourth pad layer 158d including the same layer and material as those of the touch electrodes 155 and 156.

A touch protection layer 157 may be disposed on the touch electrodes 155 and 156. In the drawings, the touch protection layer 157 is illustrated as being disposed on only the touch electrodes 155 and 156, but an embodiment is not limited thereto and the touch protection layer 157 may extend up to a previous portion or a next portion with respect to the dam DAM and may be disposed on the touch electrode connection line 152. Moreover, a color filter (not shown) may be further disposed on the encapsulation layer 120, and the color filter may be disposed on the touch layer or may be disposed between the encapsulation layer 120 and the touch layer.

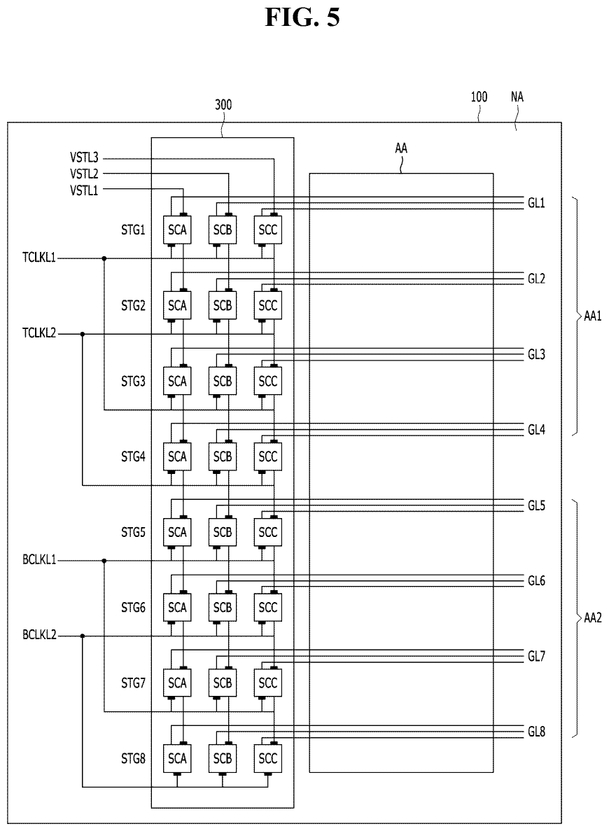

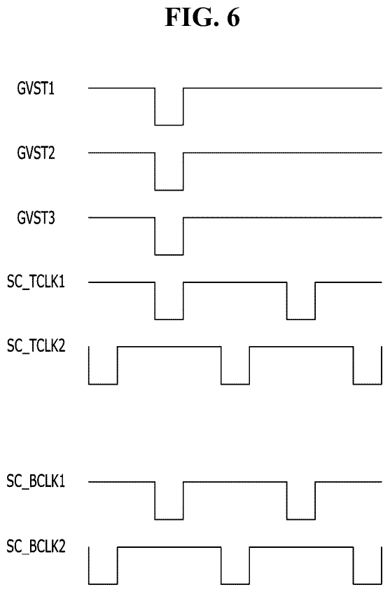

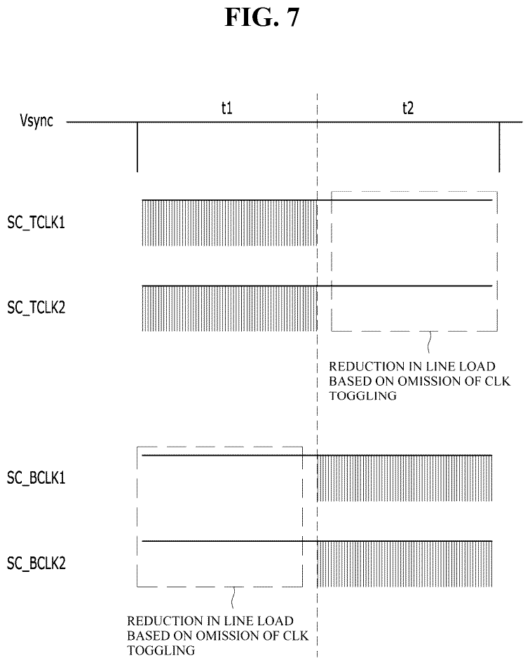

FIG. 4 is an example diagram illustrating some of elements included in a subpixel according to a first embodiment, FIG. 5 is an example diagram illustrating a shift register included in a gate driver according to a first embodiment, FIG. 6 is a waveform diagram illustrating clock signals applied to clock signal lines of FIG. 5 according to a first embodiment, and FIG. 7 is a waveform diagram for describing toggling of the clock signals applied to the clock signal lines of FIG. 5 according to a first embodiment.

As illustrated in FIG. 4, a subpixel SP according to a first embodiment may include a driving transistor DT, a first transistor T1, and a light emitting device OLED. The driving transistor DT may be implemented as a p type. The p-type driving transistor DT may operate in response to a low voltage. The first transistor T1 may be implemented as an n type. The n-type first transistor T1 may operate in response to a high voltage. The light emitting device OLED may emit light with a driving current generated based on an operation of each of the driving transistor DT and the first transistor T1.

As illustrated in FIGS. 5 and 6, a gate driver 300 according to a first embodiment may include stages STG1 to STG8 of a shift register. The stages STG1 to STG8 of the shift register may respectively output scan signals through gate lines GL1 to GL8. For example, a first stage STG1 of the shift register may output the scan signals through a first gate line GL1, a second stage STG2 of the shift register may output the scan signals through a second gate line GL2, and a third stage STG3 of the shift register may output the scan signals through a second gate line GL3.

Each of the stages STG1 to STG8 of the shift register may include a first scan signal generator SCA, a second scan signal generator SCB, and a third scan signal generator SCC. Each of the stages STG1 to STG8 of the shift register may be variously configured based on a configuration and a driving mode of a subpixel as well as a structure described above with reference to FIG. 2.

However, for convenience of description associated with a first embodiment, only three signal generators such as the first scan signal generator SCA, the second scan signal generator SCB, and the third scan signal generator SCC for outputting three scan signals are illustrated. Also, an arrangement structure of the first scan signal generator SCA, the second scan signal generator SCB, and the third scan signal generator SCC may be modified based on a structure and a driving mode of a subpixel disposed in a display area AA, and thus, for convenience of description, the elements may be arranged in order from a left side.

The first scan signal generator SCA, the second scan signal generator SCB, and the third scan signal generator SCC of each of first to eighth stages STG1 to STG8 may simultaneously start an operation, based on first to third start signals GVST1 to GVST3 having the same phase applied through first to third start signal lines VSTL1 to VSTL3.

The first scan signal generator SCA of the first stage STG1 may start an operation for an output of the first scan signal, based on the first start signal GVST1 applied through the first start signal line VSTL1. The first scan signal generator SCA of the second stage STG2 may start an operation, based on a signal (a first scan signal or a first carry signal) output from the first scan signal generator SCA of the first stage STG1 disposed at a previous end. Hereinafter, the first scan signal generator SCA of the third stage STG3 to the first scan signal generator SCA of the eighth stage STG8 may have a dependent connection relationship having the same type as the first scan signal generator SCA of the first stage STG1 and the first scan signal generator SCA of the second stage STG2. Therefore, an operation may be sequentially (or in reverse order) performed up to the first scan signal generator SCA of the eighth stage STG8 from the first scan signal generator SCA of the first stage STG1, and thus, the first scan signal may be output.

The second scan signal generator SCB of the first stage STG1 may start an operation for an output of the second scan signal, based on the second start signal GVST2 applied through the second start signal line VSTL2. The second scan signal generator SCB of the second stage STG2 may start an operation, based on a signal (a second scan signal or a second carry signal) output from the second scan signal generator SCB of the first stage STG1 disposed at a previous end.

Hereinafter, the second scan signal generator SCB of the third stage STG3 to the second scan signal generator SCB of the eighth stage STG8 may have a dependent connection relationship having the same type as the second scan signal generator SCB of the first stage STG1 and the second scan signal generator SCB of the second stage STG2. Therefore, an operation may be sequentially (or in reverse order) performed up to the second scan signal generator SCB of the eighth stage STG8 from the second scan signal generator SCB of the first stage STG1, and thus, the second scan signal may be output.

The third scan signal generator SCC of the first stage STG1 may start an operation for an output of the third scan signal, based on the third start signal GVST3 applied through the third start signal line VSTL3. The third scan signal generator SCC of the second stage STG2 may start an operation, based on a signal (a third scan signal or a third carry signal) output from the third scan signal generator SCC of the first stage STG1 disposed at a previous end.

Hereinafter, the third scan signal generator SCC of the third stage STG3 to the third scan signal generator SCC of the eighth stage STG8 may have a dependent connection relationship having the same type as the third scan signal generator SCC of the first stage STG1 and the third scan signal generator SCC of the second stage STG2. Therefore, an operation may be sequentially (or in reverse order) performed up to the third scan signal generator SCC of the eighth stage STG8 from the third scan signal generator SCC of the first stage STG1, and thus, the third scan signal may be output.

According to a first embodiment, each of the stages STG1 to STG8 of the shift register may be connected to clock signal lines physically divided into an odd-stage clock signal line and an even-stage clock signal line, so as to transfer a clock signal divided based on a disposed region and position. The clock signal lines may be formed of the same material in the same layer as a source/drain electrode of a transistor configuring a shift register. However, the clock signal lines may be formed of the same material in the same layer as a gate electrode, a semiconductor layer, an anode electrode, or a cathode electrode, based on a design.

According to a first embodiment, the clock signal lines may be divided into first group clock signal lines TCLKL1 and TCLKL2 for driving a first display area AA1 and second group clock signal lines BCLKL1 and BCLKL2 for driving a second display area AA2.

Furthermore, in a first embodiment, as a display area is divided into two display areas, clock signal lines may be divided into two group clock signal lines. However, in a case where a display area is divided into four display areas, clock signal lines may be divided into four group clock signal lines. That is, clock signal lines may be grouped based on the number of display areas.

In the first display area AA1 of the display area AA, the first scan signal generator SCA, the second scan signal generator SCB, and the third scan signal generator SCC of each of the first stage STG1 and the third stage STG3 disposed in an odd stage may be connected to a first group odd clock signal line TCLKL1 (an odd-stage clock signal line of the first display area). In the first display area AA1 of the display area AA, the first scan signal generator SCA, the second scan signal generator SCB, and the third scan signal generator SCC of each of the second stage STG2 and the fourth stage STG4 disposed in an even stage may be connected to a first group even clock signal line TCLKL2 (an even-stage clock signal line of the first display area).

In the second display area AA2 of the display area AA, the first scan signal generator SCA, the second scan signal generator SCB, and the third scan signal generator SCC of each of the fifth stage STG5 and the seventh stage STG7 disposed in an odd stage may be connected to a second group odd clock signal line BCLKL1 (an odd-stage clock signal line of the second display area). In the second display area AA2 of the display area AA, the first scan signal generator SCA, the second scan signal generator SCB, and the third scan signal generator SCC of each of the sixth stage STG6 and the eighth stage STG8 disposed in an even stage may be connected to a second group even clock signal line BCLKL2 (an even-stage clock signal line of the second display area).

A first group odd clock signal SC_TCLK1 transferred through the first group odd clock signal line TCLKL1 and a second group odd clock signal SC_BCLK1 transferred through the second group odd clock signal line BCLKL1 may have the same phase. A first group even clock signal SC_TCLK2 transferred through the first group even clock signal line TCLKL2 and a second group even clock signal SC_BCLK2 transferred through the second group even clock signal line BCLKL2 may have the same phase. The first group odd clock signal SC_TCLK1 and the second group odd clock signal SC_BCLK1 may have a phase difference so that waveforms generated with a low voltage do not overlap, compared to the first group even clock signal SC_TCLK2 and the second group even clock signal SC_BCLK2.

In FIG. 5, in clock signal lines, it is illustrated and described that odd lines are integrated together, even lines are integrated together, and the lines are connected to one clock signal line in common. However, this is merely an embodiment, and in a first embodiment, it should be construed that clock signal lines capable of being integrated and used for each stage are integrated into one, when implementing the gate driver 300.

As illustrated in FIGS. 5 and 7, according to a first embodiment, the gate driver 300 may omit toggling of some of clock signals (state change from a high voltage to a low voltage or from a low voltage to a high voltage), so as to reduce a load value (a line load or a driving load) which is a burden on some of the stages STG1 to STG8. Hereinafter, in a first embodiment, an example may be described where a vertical synchronization signal Vsync is divided into half (t1 time and t2 time), based on two display areas, and toggling of a specific clock signal is omitted for each time.

The first group clock signals SC_TCLK1 and SC_TCLK2 for driving the first display area AA1 may be toggled for a first time t1 of the vertical synchronization signal Vsync, and then, may not be toggled and may be omitted (or maintained in a DC state) for a second time t2. The second time t2 of the vertical synchronization signal Vsync may correspond to a time at which an output of a scan signal for the first display area AA1 is completed, and thus, a clock signal for driving of the stages STG1 to STG4 may not be needed. Accordingly, when toggling of the first group clock signals SC_TCLK1 and SC_TCLK2 is omitted for the second time t2 of the vertical synchronization signal Vsync, power consumption for generating a clock signal may decrease.

The second group clock signals SC_BCLK1 and SC_BCLK2 for driving the second display area AA2 may not be toggled and may be omitted (or maintained in a DC state) for the first time t1 of the vertical synchronization signal Vsync, and then, may be toggled for the second time t2. The first time t1 of the vertical synchronization signal Vsync may correspond to a time at which an output of a scan signal for the second display area AA2 does not start, and thus, a clock signal for driving of the stages STG5 to STG8 may not be needed. Accordingly, when toggling of the second group clock signals SC_BCLK1 and SC_BCLK2 is omitted for the first time t1 of the vertical synchronization signal Vsync, power consumption for generating a clock signal may decrease.

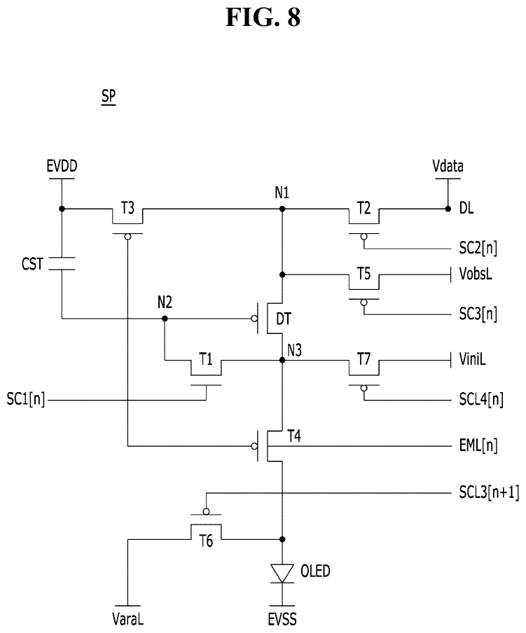

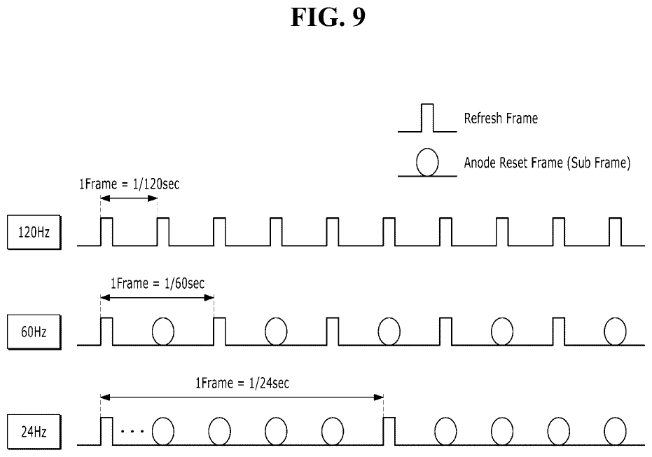

FIG. 8 is a diagram illustrating a circuit configuration of a subpixel according to a second embodiment, and FIG. 9 is a diagram for describing a driving characteristic of a display panel provided based on a subpixel according to a second embodiment.

As illustrated in FIG. 8, a subpixel SP according to a second embodiment may include a first transistor T1, a second transistor T2, a third transistor T3, a fourth transistor T4, a fifth transistor T5, a sixth transistor T6, a seventh transistor T7, a driving transistor DT, a capacitor CST, and a light emitting device OLED. In FIG. 9, for example, the first transistor T1 may be implemented as an n type based on an oxide semiconductor, and the second transistor T2, the third transistor T3, the fourth transistor T4, the fifth transistor T5, the sixth transistor T6, the seventh transistor T7, and the driving transistor DT may be implemented as a p type based on a polycrystalline semiconductor, but an embodiment is not limited thereto.

The first transistor T1 may include a gate electrode connected to a first scan line SCL1[n], a first electrode connected to a second node N2, and a second electrode connected to a third node N3. The first transistor T1 may be turned on in response to a first scan signal applied through the first scan line SCL1[n]. When the first transistor T1 is turned on, a threshold voltage of the driving transistor DT may be sampled.

The second transistor T2 may include a gate electrode connected to a second scan line SCL2[n], a first electrode connected to a data line DL, and a second electrode connected to a first node N1. The second transistor T2 may be turned on in response to a second scan signal applied through the second scan line SCL2[n]. When the second transistor T2 is turned on, a data voltage Vdata applied through the data line DL may be transferred to the first node N1.

The third transistor T3 may include a gate electrode connected to an emission control signal line EML[n], a first electrode connected to a high-level voltage line EVDD, and a second electrode connected to the first node N1. The third transistor T3 may be turned on in response to an emission control signal applied through the emission control signal line EML[n]. When the third transistor T3 is turned on, a high-level voltage applied through the high-level voltage line EVDD may be transferred to the first node N1.

The fourth transistor T4 may include a gate electrode connected to the emission control signal line EML[n], a first electrode connected to the third node N3, and a second electrode connected to an anode electrode of the light emitting device OLED. The fourth transistor T4 may be turned on in response to the emission control signal applied through the emission control signal line EML[n]. When the fourth transistor T4 is turned on, a driving current generated from the driving transistor DT may be transferred to the light emitting device OLED. When the fourth transistor T4 is turned on, the light emitting device OLED may emit light, based on the driving current generated from the driving transistor DT.

The fifth transistor T5 may include a gate electrode connected to a third scan line SCL3[n], a first electrode connected to a bias voltage line VobsL, and a second electrode connected to the first node N1. The fifth transistor T5 may be turned on in response to a third scan signal applied through the third scan line SCL3[n]. When the fifth transistor T5 is turned on, a bias voltage applied through the bias voltage line VobsL may be transferred to the first node N1. When the fifth transistor T5 is turned on, the driving transistor DT connected to the first node N1 may maintain a stronger saturation state, based on the bias voltage. Accordingly, the present disclosure may improve a phenomenon where a voltage charge time for applying a voltage to the light emitting diode OLED during an emission period is reduced or delayed.

For example, as a level of the bias voltage increases, a voltage of the third node N3 which is a drain electrode of the driving transistor DT may increase, and a gate-source voltage or a drain-source voltage of the driving transistor DT may decrease. Accordingly, it may be preferable that a level of the bias voltage is higher than that of the data voltage Vdata. Under such a condition, a magnitude of a drain source current Id passing through the driving transistor DT may decrease, and a stress of the driving transistor DT may be reduced, thereby preventing a charge delay of the third node N3. In other words, when an on bias stress operation is performed before sampling the threshold voltage of the driving transistor DT, a hysteresis of the driving transistor DT may be alleviated.

The sixth transistor T6 may include a gate electrode connected to an N^{th}+1 third scan line SCL3[n+1], a first electrode connected to a second initialization voltage line VaraL, and a second electrode connected to the anode electrode of the light emitting device OLED. The sixth transistor T6 may be turned on in response to the third scan signal applied through the N^{th}+1 third scan line SCL3[n+1]. When the sixth transistor T6 is turned on, a residual electric charge which is in the anode electrode of the light emitting device OLED may be initialized.

The seventh transistor T7 may include a gate electrode connected to a fourth scan line SC4L[n], a first electrode connected to a first initialization voltage line ViniL, and a second electrode connected to the third node N3. The seventh transistor T7 may be turned on in response to a fourth scan signal applied through the fourth scan line SC4L[n]. When the seventh transistor T7 is turned on, a first initialization voltage applied through the first initialization voltage line ViniL may be transferred to the third node N3. When the seventh transistor T7 is turned on, a residual electric charge which is in each of a second electrode of the capacitor CST and the gate electrode of the driving transistor DT connected to the third node N3 may be initialized.

The driving transistor DT may include a gate electrode connected to the second node N2, a first electrode connected to the first node N1, and a second electrode connected to the third node N3. The driving transistor DT may be driven based on the data voltage Vdata stored in the capacitor CST and may generate a driving current.

The capacitor CST may include a first electrode connected to the high-level voltage line EVDD and the second electrode connected to the second node N2. The capacitor CST may store the data voltage Vdata during a certain period, and then, may transfer the stored data voltage Vdata to the gate electrode of the driving transistor DT.

The light emitting device OLED may include the anode electrode connected to the second electrode of the fourth transistor T4 and a cathode electrode connected to a low-level voltage line EVSS. The light emitting device OLED may emit light, based on the driving current transferred through the turned-on fourth transistor T4.

As illustrated in FIG. 9, a display panel implemented based on a subpixel according to a second embodiment may operate in a variable refresh rate (VRR) mode. A VRR may be a driving mode where the display panel is driven at a certain driving frequency, and then, increases or decreases a refresh rate needed for updating of a data voltage under a high-speed driving or low-speed driving condition and reduces power consumption.

For example, the display panel implemented based on a subpixel according to a second embodiment may drive 1 frame at 120 Hz (1Frame= 1/120 sec), drive 1 frame at 60 Hz (1Frame= 1/60 sec), or drive 1 frame at 24 Hz (1Frame= 1/24 sec), and thus, may drive 1 frame at various driving speeds.

Under a high-speed driving condition such as 120 Hz, a refresh frame for refreshing (image refresh) a data voltage for each frame may be provided. On the other hand, under a low-speed driving condition such as 60 Hz or 24 Hz, an anode reset frame for refreshing a data voltage for each N frame (where N may be an integer of 1 or more) may be provided between refresh frames.

The anode reset frame may be included in a sub frame and may operate an apparatus so that normal image expression by the display panel is possible in a corresponding frame. Also, the anode reset frame may be performed under the low-speed driving condition. Therefore, the anode reset frame may correspond to a level where an image is hardly moved or a still image is displayed, and thus, only an output of a scan signal may be performed in a state where an output of a data voltage stops, but an embodiment is not limited thereto.

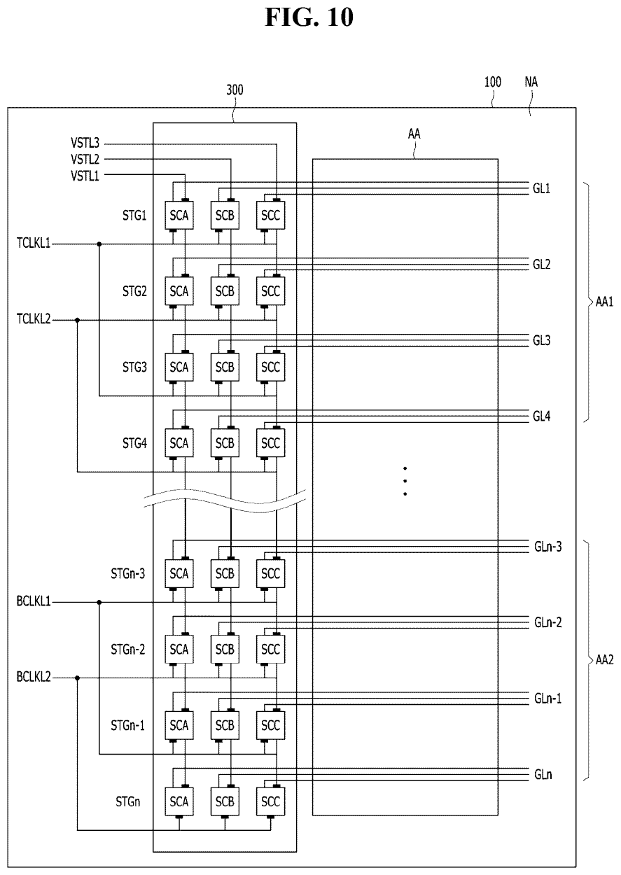

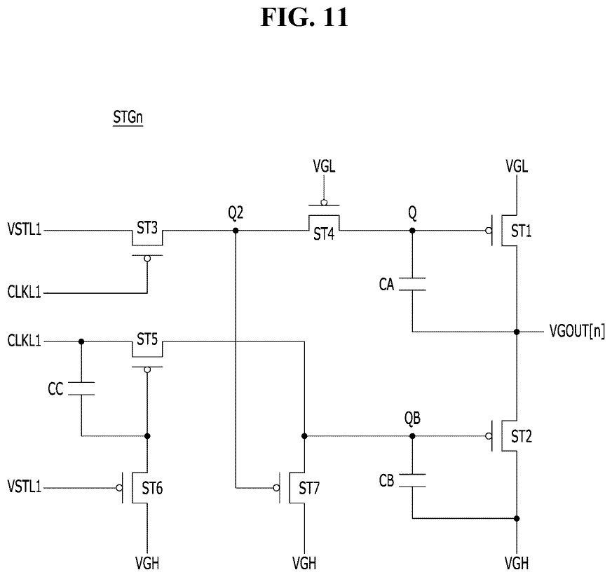

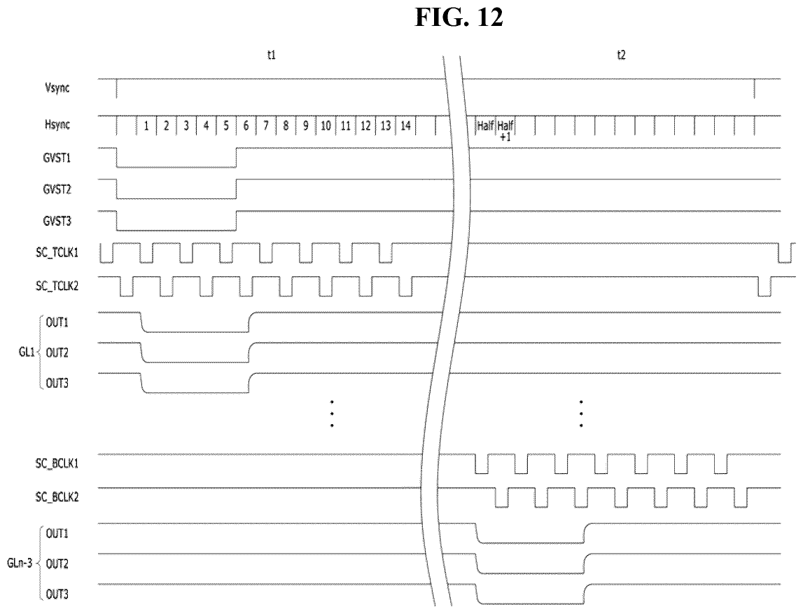

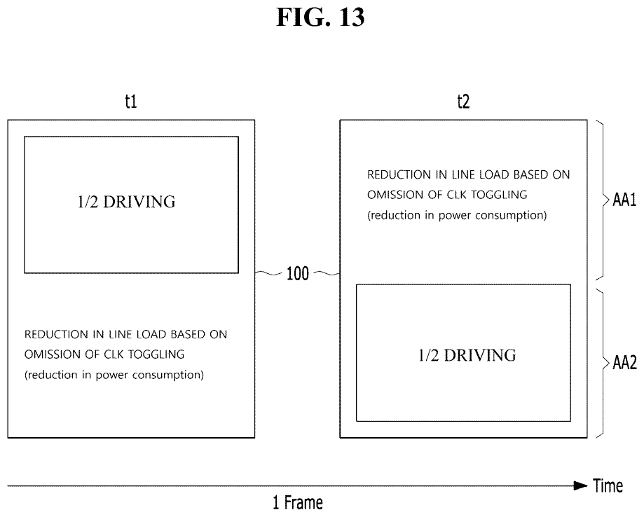

FIG. 10 is an example diagram illustrating a shift register included in a gate driver according to a second embodiment, FIG. 11 is a circuit configuration diagram illustrating an arbitrary stage in FIG. 10 according to a second embodiment, FIG. 12 is a diagram for describing toggling of clock signals applied to clock signal lines of FIG. 10 according to a second embodiment, and FIG. 13 is a diagram for describing an advantage based on toggling of clock signals according to a second embodiment.

As illustrated in FIG. 10, a gate driver 300 according to a second embodiment may include stages STG1 to STGn of a shift register. The stages STG1 to STGn of the shift register may respectively output scan signals through gate lines GL1 to GLn.

Each of the stages STG1 to STGn of the shift register may include a first scan signal generator SCA, a second scan signal generator SCB, and a third scan signal generator SCC. Each of the stages STG1 to STGn of the shift register may be variously configured based on a configuration and a driving mode of a subpixel as well as a structure described above with reference to FIG. 2.

However, for convenience of description associated with a first embodiment, only three signal generators such as the first scan signal generator SCA, the second scan signal generator SCB, and the third scan signal generator SCC for outputting three scan signals are illustrated. Also, an arrangement structure of the first scan signal generator SCA, the second scan signal generator SCB, and the third scan signal generator SCC may be modified based on a structure and a driving mode of a subpixel disposed in a display area AA, and thus, for convenience of description, the elements may be arranged in order from a left side.

The first scan signal generator SCA, the second scan signal generator SCB, and the third scan signal generator SCC of each of first to N^{th} stages STG1 to STGn may simultaneously start an operation, based on first to third start signals GVST1 to GVST3 having the same phase applied through first to third start signal lines VSTL1 to VSTL3.

According to a second embodiment, each of the stages STG1 to STGn of the shift register may be connected to clock signal lines physically divided into an odd-stage clock signal line and an even-stage clock signal line, so as to transfer a clock signal divided based on a disposed region and position.

In a first display area AA1 of the display area AA, the first scan signal generator SCA, the second scan signal generator SCB, and the third scan signal generator SCC of each of the first stage STG1 and the third stage STG3 disposed in an odd stage may be connected to a first group odd clock signal line TCLKL1 (an odd-stage clock signal line of an upper display area). Also, in the first display area AA1 of the display area AA, the first scan signal generator SCA, the second scan signal generator SCB, and the third scan signal generator SCC of each of the second stage STG2 and the fourth stage STG4 disposed in an even stage may be connected to a first group even clock signal line TCLKL2 (an even-stage clock signal line of the upper display area).

In a second display area AA2 of the display area AA, the first scan signal generator SCA, the second scan signal generator SCB, and the third scan signal generator SCC of each of an N^{th}−3 stage STGn−3 and an N^{th}−1 stage STGn−1 disposed in an odd stage may be connected to a second group odd clock signal line BCLKL1 (an odd-stage clock signal line of a lower display area). Also, in the second display area AA2 of the display area AA, the first scan signal generator SCA, the second scan signal generator SCB, and the third scan signal generator SCC of each of an N^{th}−2 stage STGn−2 and the N^{th} stage STGn disposed in an even stage may be connected to a second group even clock signal line BCLKL2 (an even-stage clock signal line of the lower display area).

A first group odd clock signal SC_TCLK1 transferred through the first group odd clock signal line TCLKL1 and a second group odd clock signal SC_BCLK1 transferred through the second group odd clock signal line BCLKL1 may have the same phase. A first group even clock signal SC_TCLK2 transferred through the first group even clock signal line TCLKL2 and a second group even clock signal SC_BCLK2 transferred through the second group even clock signal line BCLKL2 may have the same phase. The first group odd clock signal SC_TCLK1 and the second group odd clock signal SC_BCLK1 may have a phase difference so that waveforms generated with a low voltage do not overlap, compared to the first group even clock signal SC_TCLK2 and the second group even clock signal SC_BCLK2.

In FIG. 10, in clock signal lines, it is illustrated and described that odd lines are integrated together, even lines are integrated together, and the lines are connected to one clock signal line in common. However, this is merely an embodiment, and in a second embodiment, it should be construed that clock signal lines capable of being integrated and used for each stage are integrated into one, when implementing the gate driver 300. Furthermore, in FIG. 10, for convenience of description, the first to fourth stages STG1 to STG4 are illustrated as a representative stage of the upper display area AA1, and the N^{th}−3 to N^{th} stages STGn−3 to STGn are illustrated as a representative stage of the lower display area AA2. However, more stages than FIG. 10 may be actually provided.

As illustrated in FIG. 11, according to a second embodiment, the N^{th} stage STGn (or an arbitrary stage) may include first to seventh signal transistors ST1 to ST7, a compensation capacitor CC, a first capacitor CA, and a second capacitor CB. This may correspond to the stages included in the shift register, in addition to the N^{th} stage STGn. Also, in FIG. 11, the transistors included in the N^{th} stage STGn may be implemented as a p type, but an embodiment is not limited thereto.

The first signal transistor ST1 and the second signal transistor ST2 may each be an output circuit which outputs a gate signal through an output terminal VGOUT[n] of the N^{th} stage STGn. The first signal transistor ST1 and the second signal transistor ST2 may be turned on or off based on a charge/discharge operation (on or off operation) of a Q node Q and a QB node QB opposite to each other. For example, the first signal transistor ST1 may be turned on based on an electric potential of the Q node Q and may output, as a scan signal of a first voltage (on voltage), a gate low voltage applied through a gate low voltage line VGL. The second signal transistor ST2 may be turned on based on an electric potential of the QB node QB and may output, as a scan signal of a second voltage (off voltage), a gate high voltage applied through a gate high voltage line VGH.

In a case where a voltage configuring the gate low voltage in a first clock signal applied through the first clock signal line CLKL1 is transferred to the QB node QB, the compensation capacitor CC may set 0 V which is a both-end voltage and may then maintain 0 V. Based on the compensation capacitor CC, the fifth signal transistor ST5 may operate as a diode (a reverse diode) and may prevent short circuit with the gate high voltage applied through the sixth signal transistor ST6. To this end, the compensation capacitor CC may be implemented to have a capacity of hundreds pF.

Furthermore, a capacity of each of the first capacitor CA and the second capacitor CB may be set to be greater than that of the compensation capacitor CC. Also, a capacity of each of the first capacitor CA and the second capacitor CB may be set to be greater than that of the capacitor CST included in the subpixel. Also, an area of each of the first capacitor CA and the second capacitor CB may be set to be greater than that of the compensation capacitor CC. Also, an area of each of the first capacitor CA and the second capacitor CB may be set to be greater than that of the capacitor CST included in the subpixel.

The first capacitor CA and the second capacitor CB may allow a smooth and stable operation to be performed when performing an output operation of each of the first signal transistor ST1 and the second signal transistor ST2. To provide a more detailed description, the first capacitor CA may perform bootstrapping of lowering a voltage for turning on the first signal transistor ST1 at a turn-on moment so that turn-on is stably performed. To this end, the first capacitor CA may be implemented to have a capacity of hundreds pF. The second capacitor CB may hold power in a high impedance (Hi-Z) state. To this end, the second capacitor CB may be implemented to have a capacity of hundreds pF.

The third to seventh signal transistors ST3 to ST7 may each be a node control circuit which controls the charge/discharge operation of the Q node Q and the QB node QB opposite to each other. The third signal transistor ST3 may be turned on based on the first clock signal applied through the first clock signal line CLKL1 and may transfer the first start signal, applied through the first start signal line VSTL1 (start signal input terminal), to a Q2 node Q2.

The fourth signal transistor ST4 may be turned on based on the gate low voltage applied through the gate low voltage line VGL and may transfer an electric potential of the Q2 node Q2 to the Q node Q. The fifth signal transistor ST5 may be turned on based on a voltage transferred from the sixth signal transistor ST6 and may transfer the first clock signal, applied through the first clock signal line CLKL1, to the QB node QB.

The sixth signal transistor ST6 may be turned on based on the gate low voltage applied through the gate low voltage line VGL and may transfer the gate high voltage, applied through the gate high voltage line VGH, to a gate electrode of the fifth signal transistor ST5. The seventh signal transistor ST7 may be turned on based on the electric potential of the Q2 node Q2 and may transfer the gate high voltage, applied through the gate high voltage line VGH, to the QB node QB.

In a case where the Q node Q is charged based on the first start signal (or an output signal of a previous stage) applied through the first start signal line VSTL1 (start signal input terminal), the N^{th} stage STGn may output the scan signal of the first voltage (on voltage) through an output terminal VGOUT[n]. However, a connection relationship with a configuration of a circuit included in the N^{th} stage STGn may be merely for helping understand a stage configuring the shift register, and an embodiment is not limited thereto.

As illustrated in FIGS. 10, 12, and 13, the gate driver 300 according to a second embodiment may omit toggling of some of clock signals (or maintain a DC state), so as to reduce a load value (a line load or a driving load) which is a burden on some of the stages STG1 to STGn. Hereinafter, in a second embodiment, an example may be described where a vertical synchronization signal Vsync is divided into half (t1 time and t2 time), based on two display areas, and toggling of a specific clock signal is omitted for each time.

The first group clock signals SC_TCLK1 and SC_TCLK2 for driving the upper display area AA1 may be toggled for a first time t1 of the vertical synchronization signal Vsync, and then, may not be toggled and may be omitted (or maintained in a DC state) for a second time t2. The second time t2 of the vertical synchronization signal Vsync may correspond to a time at which an output of a scan signal for the upper display area AA1 is completed, and thus, a clock signal for driving of the stages STG1 to STG4 may not be needed. Accordingly, when toggling of the first group clock signals SC_TCLK1 and SC_TCLK2 is omitted for the second time t2 of the vertical synchronization signal Vsync, power consumption for generating a clock signal may decrease.

The second group clock signals SC_BCLK1 and SC_BCLK2 for driving the lower display area AA2 may not be toggled and may be omitted (or maintained in a DC state) for the first time t1 of the vertical synchronization signal Vsync, and then, may be toggled for the second time t2. The first time t1 of the vertical synchronization signal Vsync may correspond to a time at which an output of a scan signal for the lower display area AA2 does not start, and thus, a clock signal for driving of the stages STG3 to STGn may not be needed. Accordingly, when toggling of the second group clock signals SC_BCLK1 and SC_BCLK2 is omitted for the first time t1 of the vertical synchronization signal Vsync, power consumption for generating a clock signal may decrease.

Furthermore, in FIG. 12, an example is illustrated where each of first to third scan signals OUT1 to OUT3 applied to a first gate line GL1 of the upper display area AA1 and first to third scan signals OUT1 to OUT3 applied to an N^{th}−3 gate line GLn−3 of the lower display area AA2 is output as the first voltage (on voltage) at the same time. However, this may be merely an embodiment and may be modified based on a configuration and a driving mode of a subpixel. For example, at least one of the first scan signal OUT1, the second scan signal OUT2, and the third scan signal OUT3 may differ from a generating time (output time) of the first voltage (on voltage).

Hereinabove, in one or more aspects, the present disclosure may integrate some of signals, which are for driving of a display panel, into one signal (for example, a clock signal capable of integration) and may divide a region of the display panel driven by each signal, and thus, may minimize a load value (a line load or a driving load) which is an undesired burden on each signal. In addition, in one or more aspects, the present disclosure may minimize a load value (a line load or a driving load) which is an undesired burden on each signal, thereby decreasing the power consumption of a display apparatus.

While the present disclosure has been particularly shown and described with reference to example embodiments thereof, it will be understood by those of ordinary skill in the art that various changes in form and details may be made therein without departing from the spirit and scope of the present disclosure as defined by the following claims, including their equivalents.

What is claimed is:

1. A display apparatus, comprising:
a display panel configured to display an image; and
a gate driver connected to gate lines of the display panel and configured to output a scan signal which is to be applied to the gate lines, based on a clock signal,
wherein the clock signal comprises a toggling omission time.

2. The display apparatus of claim 1, wherein toggling of the clock signal is omitted for a time at which an output of a scan signal of an on voltage is completed.

3. The display apparatus of claim 2, wherein the clock signal is maintained in a direct current (DC) state for the time at which the output of the scan signal of the on voltage is completed.

4. The display apparatus of claim 1, wherein the gate driver comprises a plurality of stages, the plurality of stages are divided into a first group of stages and a second group of stages,
the first group of stages are configured to apply the scan signal to gate lines of a first display area of the display panel, and
the second group of stages are configured to apply the scan signal to gate lines of a second display area of the display panel,
wherein the first group of stages are connected to first group clock signal lines, and
the second group of stages are connected to second group clock signal lines, and
wherein the first display area is different from the second display area.

5. The display apparatus of claim 4, wherein the first group clock signal lines comprise a first group odd clock signal line connected to a scan signal generator of an odd stage of the first group of stages and a first group even clock signal line connected to a scan signal generator of an even stage of the first group of stages, and
the second group clock signal lines comprise a second group odd clock signal line connected to a scan signal generator of an odd stage of the second group of stages and a second group even clock signal line connected to a scan signal generator of an even stage of the second group of stages.

6. The display apparatus of claim 5, wherein a clock signal applied to the first group clock signal lines is toggled for a first time of a vertical synchronization signal, and then, is put in a direct current (DC) state for a second time, and
a clock signal applied to the second group clock signal lines is put in a DC state for the first time of the vertical synchronization signal, and then, is toggled for the second time.

7. The display apparatus of claim 6, wherein the first group of stages sequentially apply a scan signal of an on voltage to the gate lines of the first display area for the first time of the vertical synchronization signal, and
the second group of stages sequentially apply the scan signal of the on voltage to the gate lines of the second display area for the second time of the vertical synchronization signal.

8. The display apparatus of claim 4, wherein the first group clock signal lines and the second group clock signal lines are combined into one clock signal line.

9. A display apparatus, comprising:
a display panel configured to display an image; and
a gate driver connected to gate lines of the display panel and configured to output a scan signal which is to be applied to the gate lines, based on a clock signal,
wherein the clock signal includes a toggling time and a toggling omission time.

10. The display apparatus of claim 9, wherein the toggling omission time corresponds to a time at which an output of a scan signal of an on voltage is completed.

11. The display apparatus of claim 10, wherein the clock signal is maintained in a direct current (DC) state for the toggling omission time.

12. The display apparatus of claim 9, wherein the display panel comprises a first display area and a second display area different from the first display area,
first group clock signals for driving the first display area are toggled for the toggling time corresponding to a first time of a vertical synchronization signal, and are omitted for the toggling omission time corresponding to a second time of the vertical synchronization signal, and
second group clock signals for driving the second display area are toggled for the toggling time corresponding to the second time of the vertical synchronization signal, and are omitted for the toggling omission time corresponding to the first time of the vertical synchronization signal.

13. A gate driving circuit, comprising:
a plurality of clock signal lines; and
a plurality of stages configured to output a scan signal, based on a clock signal transferred through the plurality of clock signal lines,
wherein the clock signal comprises a toggling omission time.

14. The gate driving circuit of claim 13, wherein toggling of the clock signal is omitted for a time at which an output of a scan signal of an on voltage is completed.

15. The gate driving circuit of claim 14, wherein the clock signal is maintained in a direct current (DC) state for the toggling omission time.

16. The gate driving circuit of claim 13, wherein the plurality of stages are divided into a first group of stages and a second group of stages, the plurality of clock signal lines are divided into first group clock signal lines transmitting first group clock signals and second group clock signal lines transmitting second group clock signals,
wherein the first group of stages are connected to the first group clock signal lines,
wherein the second group of stages are connected to the second group clock signal lines,
wherein the first group clock signals are toggled for a first time of a vertical synchronization signal, and then, are put in a direct current state for a second time, and
wherein the second group clock signals are put in a DC state for the first time of the vertical synchronization signal, and then, are toggled for the second time.
